(19) United States
(12) Patent Application Publication
(10) Pub. No.: US 2024/0387462 A1
(43) Pub. Date: Nov. 21, 2024

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventor: Junbae KIM, Suwon-si (KR)

(73) Assignee: Samsung Electronics Co., Ltd., Suwon-si (KR)

(21) Appl. No.: 18/538,327

(22) Filed: Dec. 13, 2023

(30) Foreign Application Priority Data
May 19, 2023 (KR) 10-2023-0064882

(51) Int. Cl. H01L 25/065; H01L 23/00; H01L 23/528; H01L 23/60; H01L 25/10; H10B 80/00

(52) U.S. Cl. CPC H01L 25/0657; H01L 23/528; H01L 23/60; H01L 24/32; H01L 24/48; H01L 24/73; H01L 25/105; H10B 80/00; H01L 2224/32145; H01L 2224/32225; H01L 2224/48227; H01L 2224/73265; H01L 2225/0651; H01L 2225/1023; H01L 2225/1058; H01L 2924/1431; H01L 2924/1436

(57) ABSTRACT

A semiconductor device includes a semiconductor substrate, a peripheral circuit area including an input/output circuit, a electrostatic discharge (ESD) clamp circuit, and control logic, center pads above the peripheral circuit area in a vertical direction, orthogonal to an upper surface of the semiconductor substrate, and electrically connected to the input/output circuit and the center ESD clamp circuit, edge pads adjacent to a first edge of the semiconductor substrate and higher than the plurality of center pads in the vertical direction, and redistribution patterns connected to the plurality of edge pads and extending in a first direction, parallel to the upper surface of the semiconductor substrate. At least one redistribution pattern, among the redistribution patterns, is connected to at least one uppermost wiring pattern at the same height as the center pads by uppermost vias, on both sides of the center pads in the first direction.

### CROSS-REFERENCE TO RELATED APPLICATION(S)

This application claims the benefit under 35 USC 119 (a) of Korean Patent Application No. 10-2023-0064882 filed on May 19, 2023 in the Korean Intellectual Property Office, the entire disclosure of which is incorporated herein by reference for all purposes.

### BACKGROUND

The present inventive concepts relate to semiconductor devices and semiconductor packages.

A semiconductor device includes a plurality of semiconductor elements, and the semiconductor device may include pads for providing an electrical connection to other external semiconductor devices and the like. For efficient design, a semiconductor device may have a center pad structure in which a pad is disposed in a region adjacent to the center. In the case of connecting a pad to a wire in a semiconductor device having a center pad structure, redistribution patterns may be formed to connect the center pad to an edge pad disposed close to the edge of the semiconductor device in order to significantly reduce an increase in the length of the wire. In this case, since the power supply voltage is transferred through the redistribution patterns, the integrity of the power supply voltage may deteriorate.

### SUMMARY

Example embodiments provide semiconductor devices in which integrity of power supply voltage may be improved and simultaneously damage to semiconductor devices that may occur due to Electrostatic Discharge (ESD) around an edge pad connected to a redistribution pattern or the like may be effectively prevented or reduced.

According to example embodiments, a semiconductor device includes a semiconductor substrate, a peripheral circuit area including an input/output circuit, a center electrostatic discharge (ESD) clamp circuit, and control logic, a plurality of center pads above the peripheral circuit area in a vertical direction, orthogonal to an upper surface of the semiconductor substrate, and electrically connected to the input/output circuit and the center ESD clamp circuit, a plurality of edge pads adjacent to a first edge of the semiconductor substrate and higher than the plurality of center pads in the vertical direction, and a plurality of redistribution patterns extending in a first direction, parallel to the upper surface of the semiconductor substrate, and connected to the plurality of edge pads in the first direction. At least one redistribution pattern, among the plurality of redistribution patterns, is connected to at least one uppermost wiring pattern at the same height as the plurality of center pads by a plurality of uppermost vias, on both sides of the plurality of center pads in the first direction.

According to example embodiments, a semiconductor device includes a device region having a semiconductor substrate, a plurality of bank regions including a plurality of memory cells on the semiconductor substrate, and a peripheral circuit area including a plurality of semiconductor elements on the semiconductor substrate, a wiring region including a plurality of wiring patterns connected to the plurality of semiconductor elements and a plurality of center pads connected to the plurality of wiring patterns, and on the device region, and a redistribution region including a plurality of redistribution patterns connected to at least a portion of the plurality of wiring patterns, and a plurality of edge pads connected to the plurality of redistribution patterns and adjacent to a first edge of the semiconductor substrate, and above the wiring region. The device region includes a first clamp circuit area adjacent to the first edge and below the plurality of edge pads, and a second clamp circuit area below the plurality of center pads.

According to example embodiments, a semiconductor package includes a package substrate including a plurality of pads exposed on an upper surface, a semiconductor device on the package substrate, and including a semiconductor substrate, a plurality of edge pads adjacent to a first edge of the semiconductor substrate and exposed externally, and a plurality of redistribution patterns connected to the plurality of edge pads, and a plurality of wires crossing the first edge and connecting the plurality of pads and the plurality of edge pads. The semiconductor device is connected to a first edge power pad configured to receive a first power supply voltage and a second edge power pad configured to receive a second power supply voltage lower than the first power supply voltage among the plurality of edge pads, and includes edge clamp circuits adjacent to the first edge.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a schematic diagram illustrating a semiconductor package according to some example embodiments;

FIG. 2 is a schematic block diagram of a semiconductor package including a semiconductor device according to some example embodiments;

FIG. 3 is a schematic diagram of a semiconductor device according to some example embodiments;

FIG. 4 is a schematic diagram of a semiconductor device according to some example embodiments;

FIG. 5 is a schematic diagram of a semiconductor device according to some example embodiments;

FIGS. 6 and 7 are schematic diagrams illustrating a vertical structure of a semiconductor device according to some example embodiments;

FIGS. 8 and 9 are schematic diagrams illustrating a vertical structure of a semiconductor device according to some example embodiments;

FIG. 10 is a diagram schematically illustrating a partial region in which edge pads are disposed in a semiconductor device according to some example embodiments;

FIG. 11 is a diagram schematically illustrating a partial region in which center pads are disposed in a semiconductor device according to some example embodiments;

FIGS. 12 and 13 are circuit diagrams schematically illustrating ESD protection circuits included in a semiconductor device according to some example embodiments; and

FIGS. 14 and 15 are schematic diagrams illustrating semiconductor packages according to some example embodiments.

### DETAILED DESCRIPTION

Hereinafter, example embodiments will be described with reference to the accompanying drawings.

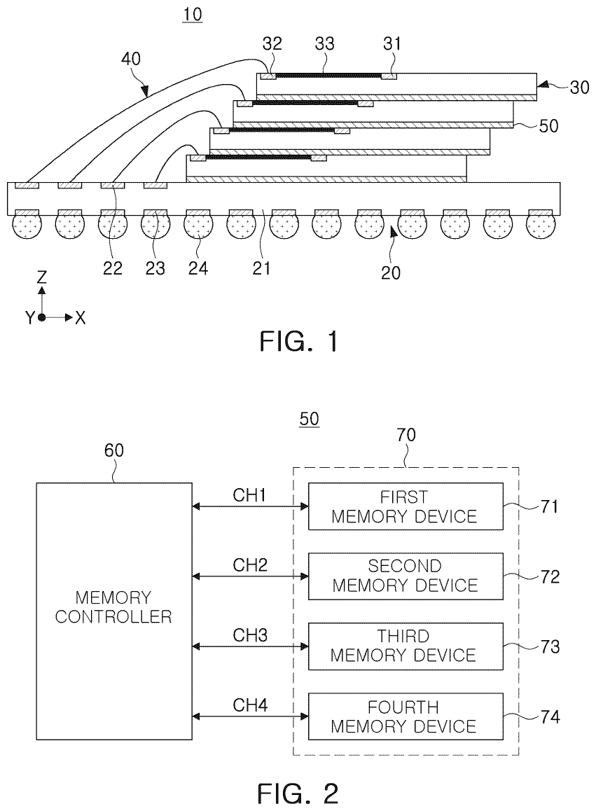

FIG. 1 is a schematic diagram illustrating a semiconductor package according to some example embodiments.

Referring to FIG. 1, a semiconductor package 10 according to some example embodiments may include a package substrate 20, a plurality of semiconductor devices 30, wires 40, and the like. The package substrate 20 may include a base substrate 21, upper pads 22, lower pads 23, and bumps 24. The bumps 24 may be connected to the lower pads 23 to provide a connection to other external semiconductor devices, substrates, and the like.

A plurality of wirings may be formed in the base substrate 21, and the upper pads 22 may be connected to the lower pads 23 by a plurality of wirings. The upper pads 22 are exposed on the upper surface of the base substrate 21, and may be disposed along at least one of a first direction (X-axis direction) and a second direction (Y-axis direction) parallel to the upper surface of the base substrate 21. The upper pads 22 may be connected to one end of the wires 40.

The plurality of semiconductor devices 30 may be stacked on the upper surface of the package substrate 20. The plurality of semiconductor devices 30 are attached to each other by an adhesive layer 50 disposed therebetween, and in some example embodiments illustrated as in FIG. 1, the plurality of semiconductor devices 30 may be stacked in a stepped structure in the first direction. Therefore, the edge pads 32 included in the plurality of respective semiconductor devices 30 are exposed externally in a third direction (Z-axis direction) perpendicular to the upper surface of the package substrate 20, and may be connected to the other ends of the wires 40.

The plurality of semiconductor devices 30 may respectively include center pads 31, edge pads 32, and redistribution patterns 33. The redistribution patterns 33 may extend in the first direction to connect the center pads 31 to the edge pads 32. Although briefly illustrated in FIG. 1, the edge pads 32 may be disposed to be relatively higher than the center pads 31 in the third direction. For example, the edge pads 32 may be provided by exposing some regions of the redistribution patterns 33 externally. As described above, the edge pads 32 are connected to the wires 40, and therefore, the plurality of respective semiconductor devices 30 may exchange signals with other external devices through the center pads 31, the redistribution patterns 33, the edge pads 32, the wires 40, and the package substrate 20.

The plurality of semiconductor devices 30 may receive not only the signal, but also the power supply voltage through the same path as the signal. In detail, the power supply voltage transmitted through the package substrate 20 and the wires 40 may be input to the plurality of respective semiconductor devices 30 through the edge pads 32, the redistribution patterns 33, and the center pads 31. As such, since the power supply voltage is transmitted through the edge pads 32 and the redistribution patterns 33 instead of being directly input to the center pads 31, inductance and/or resistance of the power supply voltage transfer path increases, and as a result, power integrity of the power supply voltage received by the plurality of semiconductor devices 30 may be deteriorated.

In some example embodiments of the present inventive concepts, among the redistribution patterns 33, at least one redistribution pattern receiving the power supply voltage may be formed longer than other redistribution patterns, for example, a redistribution pattern receiving a clock signal. In addition, the redistribution pattern receiving the power supply voltage may be connected to one of wiring patterns disposed at a height lower than the redistribution patterns through a plurality of vias, unlike the redistribution pattern receiving the signal. A plurality of vias connecting a redistribution pattern receiving a power supply voltage to one of the wiring patterns may be disposed on both sides of the center pads 31 in the first direction. Therefore, the inductance and resistance of the redistribution pattern receiving the power supply voltage may be lowered, and the integrity of the power supply voltage may be improved.

FIG. 2 is a schematic block diagram of a semiconductor package including a semiconductor device according to some example embodiments.

Referring to FIG. 2, a semiconductor package 50 according to some example embodiments may include a memory controller 60 and a plurality of memory devices 71 to 74 (70). Each of the plurality of memory devices 70 may include center pads, edge pads, and redistribution patterns connecting the edge pads and center pads.

As an example, each of the plurality of memory devices 70 may be a dynamic random access memory (DRAM) device, and bank regions including memory cells capable of storing data may be disposed on both sides of the peripheral circuit area disposed in the center. Accordingly, the center pads may be disposed above the peripheral circuit area and connected to the input/output circuits of the peripheral circuit area. In some example embodiments, the redistribution patterns may extend from the center pads onto the bank regions on both sides thereof and be connected to the edge pads.

The plurality of memory devices 70 may be connected to the memory controller 60 through memory channels CH1 to CH4. The memory controller 60 may be mounted on one package substrate together with the plurality of memory devices 70 or may be mounted on another package substrate.

For example, when the memory controller 60 is mounted on one package substrate together with the plurality of memory devices 70, the plurality of memory devices 70 are mounted on a package substrate in a stepped structure as described with reference to FIG. 1, and the edge pads of the plurality of memory devices 70 may be connected to the pads exposed on the upper surface of the package substrate through wires. The memory controller 60 is mounted on a package substrate by a flip chip bonding method, or a pad exposed on the upper surface of the memory controller 60 may be connected to a pad of the package substrate through separate wires. Accordingly, the memory controller 60 and the plurality of memory devices 70 may be electrically connected to each other through wires formed inside the package substrate.

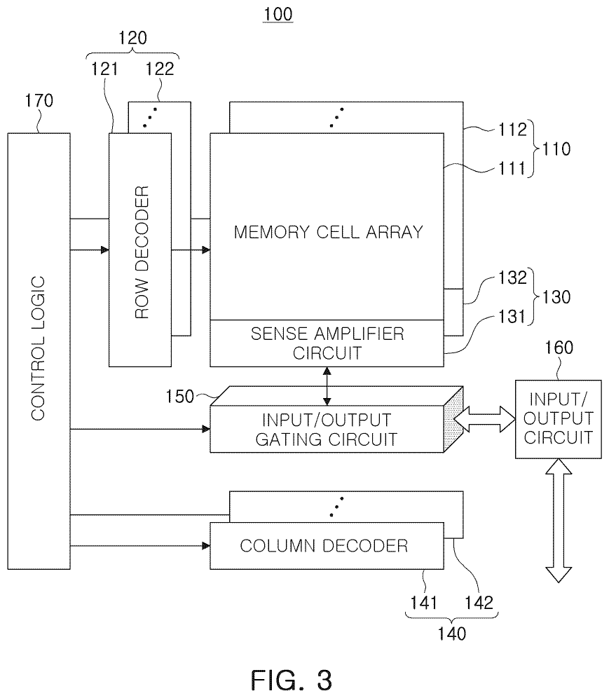

FIG. 3 is a schematic diagram of a semiconductor device according to some example embodiments.

Referring to FIG. 3, a semiconductor device 100 according to some example embodiments may include a memory cell array 110, a row decoder 120, a sense amplifier circuit 130, a column decoder 140, an input/output gating circuit 150, an input/output circuit 160, a control logic 170, and the like. For example, the semiconductor device 100 may be a dynamic random access memory device.

The memory cell array 110 may include a plurality of memory cell arrays 111 and 112, and the row decoder 120 may include a plurality of row decoders 121 and 122. In addition, the sense amplifier circuit 130 includes a plurality of sense amplifier circuits 131 and 132, and the column decoder 140 may include a plurality of column decoders 141 and 142. The plurality of memory cell arrays 111 and 112, the plurality of row decoders 121 and 122, the plurality of sense amplifier circuits 131 and 132, and the plurality of column decoders 141 and 142 are matched to each other, respectively, thereby providing a plurality of bank regions.

In detail, in each of the plurality of bank regions, the plurality of memory cell arrays 111 and 112, the plurality of row decoders 121 and 122, the plurality of sense amplifier circuits 131 and 132, and the plurality of column decoders 141 and 142 may be included one by one. Each of the plurality of memory cell arrays 111 and 112 may include a plurality of memory cells connected to intersections of a plurality of word lines connected to one of the plurality of row decoders 121 and 122 and a plurality of bit lines connected to one of the plurality of sense amplifier circuits 131 and 132. Each of the plurality of memory cells may include a switch element and a cell capacitor. The number of bank regions included in the semiconductor device 100 may be variously determined according to example embodiments.

The control logic 170 may control overall operations of the semiconductor device 100 by receiving address information and command information from an external memory controller. For example, the control logic 170 may control operations of the row decoder 120 and the column decoder 140 based on bank address information, row address information, and column address information included in the address information.

The control logic 170 may generate control signals to allow the semiconductor device 100 to perform a write operation, a read operation, a refresh operation, and the like. The control logic 170 may determine an operation mode of the semiconductor device 100 by decoding command information received from the memory controller. For example, the control logic 170 decodes the command information received from the memory controller, and may generate a write enable signal, a row address strobe signal, a column address strobe signal, a chip select signal, and the like.

The input/output gating circuit 150 may include an input data mask logic, read data latches for storing data read from the memory cell array 110 in a plurality of bank regions, write drivers for storing data in the memory cell array 110, and the like, along with circuits for gating input and output data. For example, when the sense amplifier circuit 130 acquires data stored in at least one of a plurality of memory cells included in the memory cell array 110, data obtained by the sense amplifier circuit 130 may be stored in the read data latches. Data stored in the read data latches may be transmitted to an external memory controller through the input/output circuit 160.

Data to be stored in the memory cell array 110 is transferred from the memory controller through the input/output circuit 160, and the transferred data may be written to a portion of the memory cells included in the memory cell array 110 through the write drivers of the input/output gating circuit 150. In this manner, the input/output circuit 160 exchanges signals with the external memory controller, and may include an output driver, a receiver, and the like.

The input/output circuit 160 may be connected to pads exposed to the outside of the semiconductor device 100 to output signals to the pads or to receive signals transmitted to the pads. Therefore, in the case in which Electrostatic Discharge (ESD) or the like occurs around the semiconductor device 100, an overcurrent due to ESD may flow into an internal circuit such as the input/output circuit 160 and the like through the pads, causing damage to the semiconductor device 100. To prevent or reduce such damage, the input/output circuit 160 may include an ESD protection circuit connected to the pads.

The pads connected to the input/output circuit 160 may be physically disposed close to the input/output circuit 160. The control logic 170, the input/output gating circuit 150, and the input/output circuit 160 are disposed in a peripheral circuit area different from the bank regions, and in the semiconductor device 100, bank regions may be disposed on both sides of the peripheral circuit area. This may be to reduce the distance between the peripheral circuit area including the control logic 170 and each of the bank regions.

In this case, the pads connected to the input/output circuit 160 are disposed above the peripheral circuit area, and thus the semiconductor device 100 may have a center pad structure. In the semiconductor device 100 having a center pad structure, when pads are to be connected to wires, the redistribution patterns extending from the pads may be formed to significantly reduce an increase in the length of the wires. The redistribution patterns may extend in a predetermined direction to an area adjacent to an edge of the semiconductor device 100 to provide edge pads.

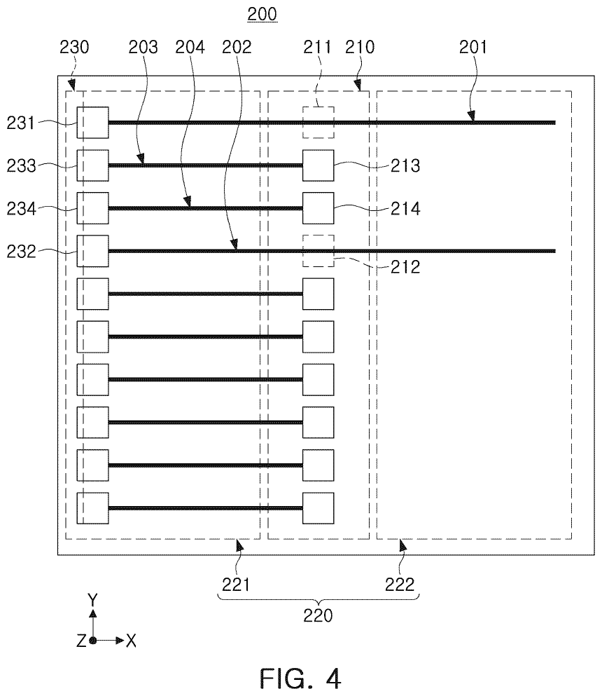

FIG. 4 is a schematic diagram of a semiconductor device according to some example embodiments.

Referring to FIG. 4, a semiconductor device 200 according to some example embodiments may include a peripheral circuit area 210 and a cell area 220. As described above with reference to FIG. 3, a control logic, an input/output gating circuit, an input/output circuit, and the like are disposed in the peripheral circuit area 210, and the cell area 220 may be disposed on both sides of the peripheral circuit area 210 in the first direction (X-axis direction).

The cell area 220 includes a first cell area 221 disposed on one side of the peripheral circuit area 210 and a second cell area 222 disposed on the other side of the peripheral circuit area 210, and two or more bank regions may be disposed in each of the first cell area 221 and the second cell area 222. Each of the bank regions includes a memory cell array, a row decoder, a sense amplifier circuit, a column decoder, and the like, and the control logic of the peripheral circuit area 210 controls row decoders and column decoders of each of the bank regions to write data into the memory cell array, or may execute control operations such as reading data recorded in the memory cell array.

An input/output circuit disposed in the peripheral circuit area 210 may be connected to a plurality of center pads 211 to 214 disposed above the peripheral circuit area 210. By forming the plurality of center pads 211 to 214 above the peripheral circuit area 210, resistance characteristics may be improved by reducing the lengths of wiring patterns connecting the plurality of center pads 211 to 214 and the input/output circuit.

In some example embodiments, the plurality of center pads 211 to 214 may be connected to the plurality of edge pads 231 to 234 disposed adjacent to an edge of one side of the semiconductor device 200 by the plurality of redistribution patterns 201 to 204 extending in the first direction. The plurality of edge pads 231 to 234 and the plurality of redistribution patterns 201 to 204 may be disposed to be higher than the center pads 211 to 214 in a vertical direction (Z-axis direction) perpendicular to the upper surface of the semiconductor substrate included in the semiconductor device 200.

The plurality of redistribution patterns 201 to 204 may extend in a first direction parallel to the upper surface of the semiconductor substrate, and be arranged in a second direction (Y-axis direction) crossing the first direction. In some example embodiments, as illustrated in FIG. 4, the lengths of portions of the redistribution patterns 201 and 202 in the first direction may be greater than the lengths of the remaining redistribution patterns 203 and 204.

For example, the first redistribution pattern 201 and the second redistribution pattern 202 may cross the plurality of center pads 211 to 214, and may extend by a length substantially crossing the semiconductor device 200 in the first direction. In detail, the first redistribution pattern 201 and the second redistribution pattern 202 may extend from a first edge to which the plurality of edge pads 231 to 234 are adjacent to an area adjacent to a second edge opposite to and facing the first edge. Accordingly, the first redistribution pattern 201 and the second redistribution pattern 202 are disposed on both sides of the peripheral circuit area 210 in the first direction, and may overlap the respective first cell area 221 and second cell area 222 in a vertical direction.

In some example embodiments, the third redistribution pattern 203 and the fourth redistribution pattern 204 may extend only from the plurality of edge pads 231 to 234 to the plurality of center pads 211 to 214. Therefore, in the vertical direction, the third redistribution pattern 203 and the fourth redistribution pattern 204 overlap with the first cell area 221, while may not overlap with the second cell area 222.

In some example embodiments, in the example embodiment illustrated in FIG. 4, the first redistribution pattern 201 directly contacts the first edge pad 231, while may not directly contact the first center pad 211. Similarly, the second redistribution pattern 202 directly contacts the second edge pad 232, while may not directly contact the second center pad 212. For example, a layer formed of an insulating material may be disposed between the first redistribution pattern 201 and the first center pad 211 and between the second redistribution pattern 202 and the second center pad 212 in the vertical direction.

The first center pad 211 may be connected to a first uppermost wiring pattern disposed at the same height as the first center pad 211 and extending in a first direction. In some example embodiments, the second center pad 212 may also be connected to a second uppermost wiring pattern disposed at the same height as the second center pad 212 and extending in the first direction. The first redistribution pattern 201 is electrically connected to the first uppermost wiring pattern through a plurality of first uppermost vias arranged in a first direction, and the second redistribution pattern 202 may be electrically connected to the second uppermost wiring pattern through a plurality of second uppermost vias arranged in the first direction. The plurality of first uppermost vias and the plurality of second uppermost vias may distributed over the first cell area 221 and the second cell area 222.

In some example embodiments, unlike the first redistribution pattern 201 and the second redistribution pattern 202, the third redistribution pattern 203 and the fourth redistribution pattern 204 may be directly connected to center pads corresponding thereto. For example, the third redistribution pattern 203 may directly contact the third center pad 213 and the fourth redistribution pattern 204 may directly contact the fourth center pad 214.

The first redistribution pattern 201 and the second redistribution pattern 202 may respectively provide transmission paths of power supply voltages. For example, the first edge pad 231 and the first redistribution pattern 201 may provide a transmission path of the first power supply voltage, and the second edge pad 232 and the second redistribution pattern 202 may provide a transmission path for a second power supply voltage lower than the first power supply voltage. For example, the second power supply voltage may be a reference voltage. As described above, the first redistribution pattern 201 and the second redistribution pattern 202, providing transmission paths for power supply voltages, extend to both sides of the peripheral circuit area 210 in the first direction, and are connected to the uppermost wiring patterns through a plurality of uppermost vias, thereby reducing the inductance and voltage of the transmission path of the power supply voltage and improving the integrity of the power supply.

Also, in some example embodiments, a protection circuit area 230 may be defined below the plurality of edge pads 231 to 234. The protection circuit area 230 is adjacent to the first edge like the plurality of edge pads 231 to 234, and at least one ESD protection circuit may be disposed. The ESD protection circuit disposed in the protection circuit area 230 may be an ESD clamp circuit electrically connected to the first edge pad 231 and the second edge pad 232 receiving power supply voltages. The ESD clamp circuit may include a Gate-Grounded NMOS (GGNMOS) device, a Gate-Coupled NMOS (GCNMOS) device, a Silicon Controlled Rectifier (SCR) circuit, and the like.

In some example embodiments, the transmission path of the first power supply voltage and the transmission path of the second power supply voltage may be connected to a plurality of ESD clamp circuits. In some example embodiments, a portion of the plurality of ESD clamp circuits connected to the transmission path of the first power supply voltage and the transmission path of the second power supply voltage is disposed in the protection circuit area 230, and the rest may be disposed in the peripheral circuit area 210. Depending on some example embodiments, the number of ESD clamp circuits disposed in the protection circuit area 230 may be the same as or different from the number of ESD clamp circuits disposed in the peripheral circuit area 210. In this manner, by disposing some ESD clamp circuits in the protection circuit area 230 below the plurality of edge pads 231 to 234, the semiconductor device 200 may be protected (or, for example, effectively protected) from overcurrent flowing into the plurality of edge pads 231 to 234 due to ESD or the like.

The first power supply voltage may be a power supply voltage required for the operation of a control logic included in the peripheral circuit area 210 of the semiconductor device 200. According to some example embodiments, the input/output circuit connected to the plurality of center pads 211 to 214 may be operated by a third power supply voltage lower than the first power supply voltage and higher than the second power supply voltage. The third power supply voltage may be supplied to the semiconductor device 200 by a redistribution pattern disposed only between the plurality of edge pads 231 to 234 and the plurality of center pads 211 to 214, such as the third redistribution pattern 203 or the fourth redistribution pattern 204. Also, like the third power supply voltage, transmission paths for clock signals, data signals and the like may also be provided by a redistribution pattern disposed only between the plurality of edge pads 231 to 234 and the plurality of center pads 211 to 214.

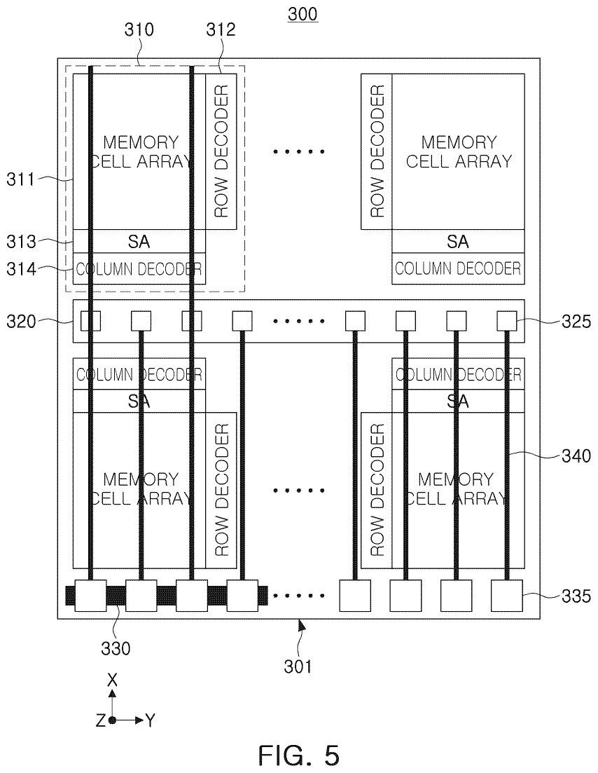

FIG. 5 is a schematic diagram of a semiconductor device according to some example embodiments.

Referring to FIG. 5, a semiconductor device 300 according to some example embodiments may be a dynamic random access memory device. The semiconductor device 300 may include a plurality of bank regions 310, a peripheral circuit area 320, and the like. A portion of the plurality of bank regions 310 may be disposed on one side of the peripheral circuit area 320 in the first direction (X-axis direction), and the rest may be disposed on the other side of the peripheral circuit area 320 in the first direction.

Each of the plurality of bank regions 310 may include a memory cell array 311, a row decoder 312, a sense amplifier circuit 313, a column decoder 314, and the like. The row decoder 312, the sense amplifier circuit 313, and the column decoder 314 may be controlled by control logic disposed in the peripheral circuit area 320, and execute a read operation, a write operation, or the like on at least one selected memory cell among a plurality of memory cells disposed in the memory cell array 311.

A plurality of center pads 325 may be disposed above the peripheral circuit area 320. The plurality of center pads 325 may be electrically connected to the input/output circuit disposed in the peripheral circuit area 320.

Outside the plurality of bank regions 310 disposed on one side of the peripheral circuit area 320, a plurality of edge pads 335 may be disposed adjacent to the first edge 301 of the semiconductor device 300. FIG. 5 illustrates that the plurality of edge pads 335 are disposed outside the plurality of bank regions 310, but unlike this, at least a portion of the plurality of edge pads 335 may be disposed overlapping the plurality of bank regions 310. The plurality of edge pads 335 may be connected to the plurality of redistribution patterns 340.

The plurality of edge pads 335 may be defined as pads disposed closer to the first edge 301 of the semiconductor device 300 than the plurality of center pads 325. As an example, the distance between the first edge and the plurality of edge pads 335 in the first direction may be smaller than the distance between the first edge and the plurality of center pads 325.

At least one redistribution pattern among the plurality of redistribution patterns 340 may extend to both sides of the peripheral circuit area 320 in the first direction as illustrated in FIG. 5. In some example embodiments, the remaining redistribution patterns may extend only between the plurality of edge pads 335 and the plurality of center pads 325. At least one redistribution pattern extending to both sides of the peripheral circuit area 320 may be connected to edge pads receiving power supply voltages required for the operation of the semiconductor device 300.

A protection circuit area 330 separated from the peripheral circuit area 320 may be disposed below the plurality of edge pads 335. The protection circuit area 330 may include ESD clamp circuits connected to edge pads to which the at least one redistribution pattern is connected. Depending on the area required to implement the ESD clamp circuits, the protection circuit area 330 may be defined only below a portion of the plurality of edge pads 335.

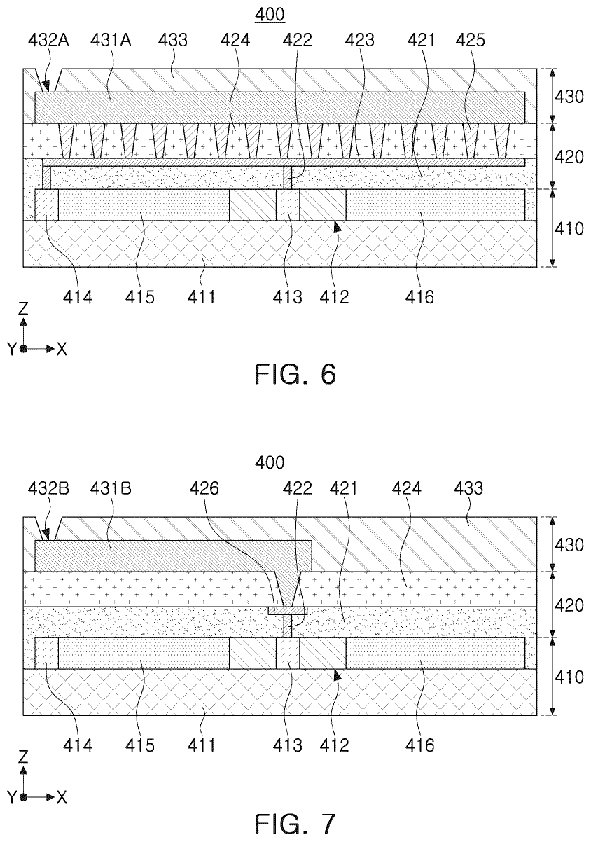

FIGS. 6 and 7 are schematic diagrams illustrating a vertical structure of a semiconductor device according to some example embodiments.

Referring to FIGS. 6 and 7, a semiconductor device may include a device region 410, a wiring region 420, and a redistribution region 430. The device region 410 may include a semiconductor substrate 411, a peripheral circuit area 412 including semiconductor elements formed on the semiconductor substrate 411, and a plurality of bank regions 415 and 416 including memory cells formed on the semiconductor substrate 411.

ESD clamp circuits may be disposed in the device region 410 to protect the semiconductor device 400 from overcurrent caused by ESD. For example, the ESD clamp circuits may be disposed in each of the first clamp circuit area 414 adjacent to an edge of the semiconductor substrate 411 and the second clamp circuit area 413 within the peripheral circuit area 412. Accordingly, the bank region 415 that is a portion of the plurality of bank regions 415 and 416 may be disposed between the first clamp circuit area 414 and the second clamp circuit area 413 in the first direction. For example, edge ESD clamp circuits may be disposed in the first clamp circuit area 414, and center ESD clamp circuits may be disposed in the second clamp circuit area 413.

The wiring region 420 may be disposed on the device region 410 in a vertical direction perpendicular to the upper surface of the semiconductor substrate 411. The wiring region 420 may include a plurality of insulating layers 421 and 424, a plurality of vias 422 and 425, a plurality of wiring patterns 423, and the like. The plurality of vias 422 and 425 and the plurality of wiring patterns 423 may be disposed in the plurality of insulating layers 421 and 424. In some example embodiments, a portion of the plurality of wiring patterns 423 may be exposed externally in an area in which the insulating layer 424 is not formed, thereby providing a center pad 426.

The redistribution region 430 is disposed above the wiring region 420, and may include a plurality of redistribution patterns 431A and 431B, a plurality of edge pads 432A and 432B, a passivation layer 433, and the like. The plurality of edge pads 432A and 432B may be formed by removing a portion of the passivation layer 433 to expose a partial region of the plurality of redistribution patterns 431A and 431B externally.

The plurality of redistribution patterns 431A and 431B may be connected to the plurality of wiring patterns 423 disposed in the wiring region 420. However, a method in which the plurality of redistribution patterns 431A and 431B are respectively connected to the wiring region 420 may be different.

Referring first to FIG. 6, the redistribution pattern 431A may be connected to the wiring pattern 423 through the plurality of uppermost vias 425. The plurality of uppermost vias 425 are arranged in the first direction (X-axis direction), and the redistribution pattern 431A and the wiring pattern 423 may also extend in the first direction. The edge pad 432A may be a pad receiving a first power supply voltage required for the operation of the semiconductor device 400 or a second power supply voltage corresponding to a reference voltage. The redistribution pattern 431A connected to the edge pad 432A receiving the first power supply voltage or the second power supply voltage is connected to the wiring pattern 423 in the structure illustrated in FIG. 6, and thus, the inductance and resistance of the transmission path of the first power supply voltage or the second power supply voltage may be reduced, and the integrity of the power supply may be improved.

The plurality of uppermost vias 425 may be a via structure directly contacting the redistribution pattern 431A. The upper surfaces of the uppermost vias 425 directly contact the redistribution pattern 431A, and the lower surfaces thereof may directly contact the wiring pattern 423. The wiring pattern 423 may be the uppermost wiring pattern disposed at the highest position from the upper surface of the semiconductor substrate 411 among the wiring patterns excluding the redistribution pattern 431A, but is not necessarily limited to this form. Depending on some example embodiments, the wiring pattern 423 contacting the lower surface of the uppermost vias 425 may be a wiring pattern disposed at a lower height than the uppermost wiring pattern.

Also, as illustrated in FIG. 6, the wiring pattern 423 receiving the first power supply voltage or the second power supply voltage may be connected to both the edge ESD clamp circuits and the center ESD clamp circuits. This may be due to a structural feature in which some of the uppermost vias 425 are also disposed in a space between the edge pad 432A and the peripheral circuit area 412 in the first direction.

Next, referring to FIG. 7, the redistribution pattern 431B may be directly connected to the center pad 426 formed on the peripheral circuit area 412. Therefore, the redistribution pattern 431B is not connected to the plurality of uppermost vias 425, and the wiring pattern 423 extending in the first direction may also not be disposed below the redistribution pattern 431B. The redistribution pattern 431B may provide a transmission path for a power supply voltage of a relatively low level required for the operation of the input/output circuit disposed in the peripheral circuit area 412, or may provide transmission paths for clock signals, data signals, and the like. The redistribution pattern 431B is separated from the first clamp circuit area 414 and may be connected only to the second clamp circuit area 413.

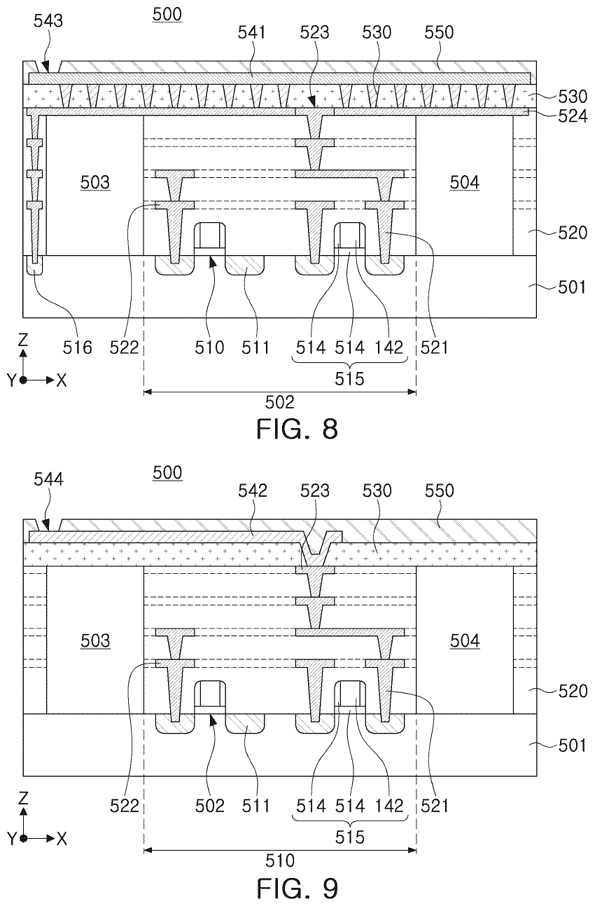

FIGS. 8 and 9 are schematic diagrams illustrating a vertical structure of a semiconductor device according to some example embodiments.

Referring to FIGS. 8 and 9, a semiconductor device 500 according to some example embodiments may include a semiconductor substrate 501, a peripheral circuit area 502, a plurality of bank regions 503 and 504, and the like. A plurality of semiconductor elements 510 providing control logic, input/output circuits, and the like may be disposed in the peripheral circuit area 502. Each of the plurality of semiconductor elements 510 may include an active region 511 providing a source/drain region and a gate structure 515. The gate structure 515 may include a gate electrode layer 512, a gate insulating layer 513, a gate spacer 514, and the like.

A plurality of memory cells are disposed in each of the plurality of bank regions 503 and 504, and each of the plurality of memory cells may include a switch element and a cell capacitor. For example, the switch element may include a buried gate electrode layer buried in the semiconductor substrate 501, and the cell capacitor may have a pillar shape disposed on the semiconductor substrate 501 and extending in a vertical direction (Z-axis direction) perpendicular to the upper surface of the semiconductor substrate 501.

The plurality of semiconductor elements 510 disposed in the peripheral circuit area 502 may be connected to a plurality of redistribution patterns 541 and 542 through the plurality of contacts 521 and the plurality of wiring patterns 522. The plurality of redistribution patterns 541 and 542 may be disposed on an interlayer insulating layer 520 in which a plurality of contacts 521 and a plurality of wiring patterns 522 are buried and an upper insulating layer 540 disposed on the interlayer insulating layer 520. The plurality of redistribution patterns 541 and 542 may respectively extend in a first direction (X-axis direction), and at least a partial region thereof may be exposed externally by a passivation layer 550 to provide a plurality of edge pads 543 and 544.

First, referring to FIG. 8, the power redistribution pattern 541 receiving one of the first power supply voltage and the second power supply voltage required for the operation of the semiconductor device 500 may extend in the first direction and be disposed on the plurality of bank regions 503 and 504. The power redistribution pattern 541 may be connected to the uppermost wiring pattern 524 disposed at the highest position among the plurality of wiring patterns 522 through the plurality of uppermost vias 531. The plurality of uppermost vias 531 may be arranged in the first direction on the peripheral circuit area 502 and the plurality of bank regions 503 and 504. Also, the power redistribution pattern 541 may not directly contact the center pad 523 on the peripheral circuit area 502.

The uppermost wiring pattern 524 connected to the power redistribution pattern 541 may be connected to at least one of the plurality of semiconductor elements 510 disposed in the peripheral circuit area 502, through the plurality of contacts 521 and the plurality of wiring patterns 522. Also, the uppermost wiring pattern 524 may be connected to the active region 516 formed below the plurality of edge pads 543 and 544. The active region 516 formed below the plurality of edge pads 543 and 544 may be an active region included in a semiconductor element providing an edge ESD clamp circuit formed outside the first bank region 503.

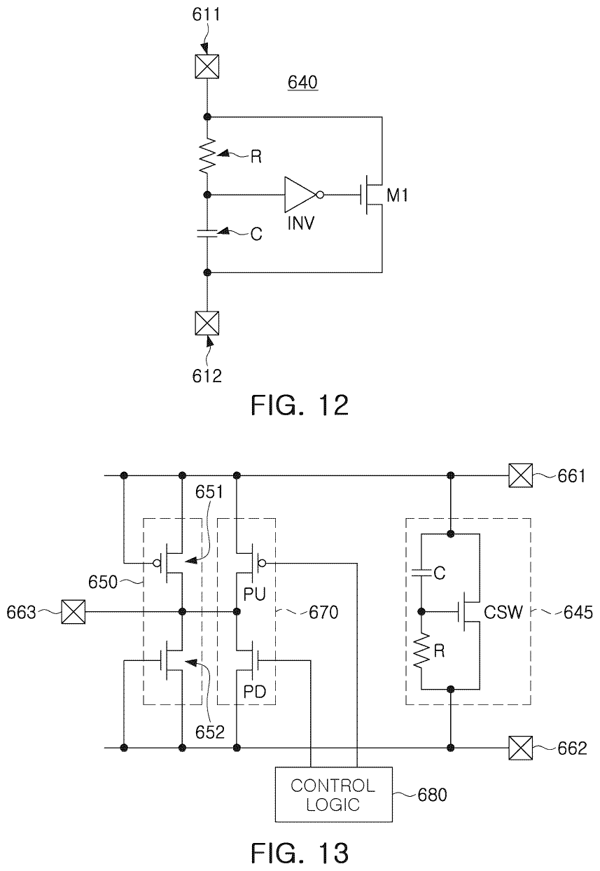

The semiconductor element 510 of the peripheral circuit area 502 connected to the uppermost wiring pattern 524 may be included in a center ESD clamp circuit for discharging overcurrent generated due to ESD around the power edge pad 543. For example, the semiconductor element 510 may provide one of a MOS capacitor and a GCNMOS device of the center ESD clamp circuit. The center ESD clamp circuit may have the same structure as the edge ESD clamp circuit formed outside the first bank region 503, and a detailed structure and operation of the ESD clamp circuit will be described later with reference to FIGS. 12 and 13.

Next, referring to FIG. 9, the signal redistribution pattern 542 for inputting and outputting clock signals, data signals, command/address signals, and the like required for the operation of the semiconductor device 500 may extend in the first direction and be disposed on the first bank region 503. In detail, the signal redistribution pattern 542 may not be formed on the second bank region 504. The signal redistribution pattern 542 may directly contact the center pad 523 without the plurality of uppermost vias 531.

Also, the signal redistribution pattern 542 may not be connected to an edge ESD clamp circuit formed outside the first bank region 503, that is, below the plurality of edge pads 543 and 544. The signal redistribution pattern 542 may be connected to the semiconductor element 510 providing the center ESD clamp circuit in the peripheral circuit area 502.

In addition to the clock signal, data signal, and command/address signal, the redistribution pattern receiving some power supply voltage may also be formed in the same structure as the signal redistribution pattern 542 illustrated in FIG. 9. As an example, the power supply voltage required for the operation of an input/output circuit disposed in the peripheral circuit area 502 to output or receive a signal may be received by a redistribution pattern having a structure similar to the signal redistribution pattern 542 instead of the power redistribution pattern 541.

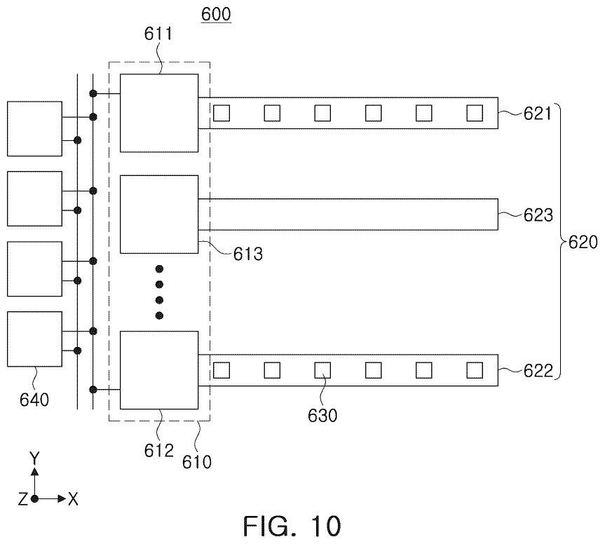

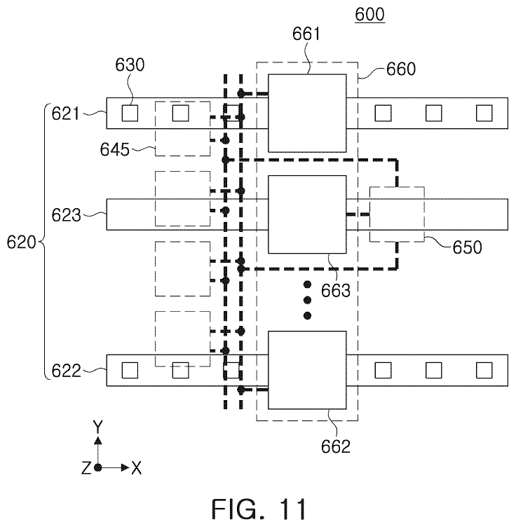

FIG. 10 is a diagram schematically illustrating a partial region in which edge pads are disposed in a semiconductor device according to some example embodiments. In some example embodiments, FIG. 11 is a diagram schematically illustrating a partial region in which center pads are disposed in a semiconductor device.

Referring first to FIG. 10, a semiconductor device 600 according to some example embodiments may include a plurality of edge pads 611 to 613 (610), a plurality of redistribution patterns 621 to 623 (620), a plurality of uppermost vias 630, a plurality of ESD clamp circuits 640, and the like. The ESD clamp circuits 640 illustrated in FIG. 10 may be edge ESD clamp circuits disposed adjacent to the plurality of edge pads 610.

The first edge pad 611 is connected to the first redistribution pattern 621, and a first power supply voltage required for the operation of the semiconductor device 600 may be applied to the first edge pad 611 through a wire. The second edge pad 612 is connected to the second redistribution pattern 622, and a second power supply voltage required for the operation of the semiconductor device 600 may be applied to the second edge pad 612 through a wire. The second power supply voltage is a voltage lower than the first power supply voltage and may be a kind of reference voltage. In some example embodiments, the third edge pad 613 may be connected to the third redistribution pattern 623 and provide transmission paths for clock signals, command/address signals, and/or data signals.

Alternatively, a third power supply voltage required for operation of an input/output circuit that receives or outputs signals may be applied to the third edge pad 613 through a wire. The third power supply voltage may be a voltage lower than the first power supply voltage and higher than the second power supply voltage.

The first redistribution pattern 621 and the second redistribution pattern 622 may be respectively connected to a plurality of uppermost vias 630. For example, the first redistribution pattern 621 may be connected to the uppermost wiring pattern therebelow extending in the first direction (X-axis direction) by the plurality of uppermost vias 630.

The plurality of ESD clamp circuits 640 may be electrically connected to the first edge pad 611 and the second edge pad 612 to receive the first power supply voltage and the second power supply voltage. For example, each of the plurality of ESD clamp circuits 640 includes an SCR circuit or may be implemented as a protection circuit including a GGNMOS device, a GCNMOS device, and the like. For example, when each of the plurality of ESD clamp circuits 640 includes a GCNMOS device, a drain region of the GCNMOS device is electrically connected to the first edge pad 611, and the source region may be electrically connected to the second edge pad 612.

Referring next to FIG. 11, a semiconductor device 600 according to some example embodiments may include a plurality of center pads 661 to 663: 660, a plurality of redistribution patterns 621 to 623: 620, a plurality of uppermost vias 630, a plurality of ESD clamp circuits 640, and the like. The plurality of ESD clamp circuits 645 illustrated in FIG. 11 may be center ESD clamp circuits disposed adjacent to the plurality of center pads 660.

The first center pad 661 is connected to the first redistribution pattern 621, and the first power supply voltage applied to the first edge pad 611 may be transferred to the peripheral circuit area through the first center pad 661. The second center pad 662 is connected to the second redistribution pattern 622, and the second power supply voltage applied to the second edge pad 612 may be transferred to the peripheral circuit area through the second center pad 662. The third center pad 663 is connected to the third redistribution pattern 623, and may provide transmission paths for clock signals, command/address signals, data signals, and the like, or transfer the third power supply voltage required for the operation of the input/output circuit to the input/output circuit in the peripheral circuit area.

The first redistribution pattern 621 and the second redistribution pattern 622 may be respectively connected to a plurality of uppermost vias 630. Referring to FIG. 11, unlike the third redistribution pattern 623, the first redistribution pattern 621 and the second redistribution pattern 622 may respectively extend to both sides of the plurality of center pads 660 in the first direction. Therefore, at least one of the first redistribution pattern 621 and the second redistribution pattern 622 may have the longest length among the plurality of redistribution patterns 620.

The plurality of center ESD clamp circuits 640 are electrically connected to the first center pad 661 and the second center pad 662, to receive the first power supply voltage and the second power supply voltage. For example, the plurality of center ESD clamp circuits 645 may respectively have the same structure as the plurality of edge ESD clamp circuits 640 described above with reference to FIG. 10. Also, the number of the plurality of center ESD clamp circuits 645 may be the same as the number of the plurality of edge ESD clamp circuits 640.

In some example embodiments, unlike the first center pad 661 and the second center pad 662, the third center pad 663 inputting and outputting signals may be connected to the ESD protection elements 650. The ESD protection elements 650 may include a first ESD diode connected between the third center pad 663 and the first center pad 661, a second ESD diode connected between the third center pad 663 and the second center pad 662, an ESD resistance element, and the like. The ESD protection elements 650 will be described later with reference to FIGS. 12 and 13.

FIGS. 12 and 13 are circuit diagrams briefly illustrating ESD protection circuits included in a semiconductor device according to some example embodiments.

For convenience of descriptions, FIGS. 12 and 13 will be described with reference to FIGS. 10 and 11 together. FIG. 12 may be a circuit diagram of an edge ESD clamp circuit 640 as an example. However, as described above, the center ESD clamp circuit 645 may also be implemented with a circuit having the same structure as the edge ESD clamp circuit 640.

Referring to FIG. 12, the edge ESD clamp circuit 640 may include a resistance element (R) connected to the first edge pad 611, a capacitor element (C) connected to the second edge pad 612, an inverter element (INV), an NMOS device (M1), and the like. The capacitor element C may be implemented as a MOS capacitor. In some example embodiments, the drain region of the NMOS device M1 is connected to the first edge pad 611 and the source region thereof is connected to the second edge pad 612. The NMOS device M1 may be a GCNMOS device.

Elements providing the edge ESD clamp circuit 640 may be formed in regions adjacent to the plurality of edge pads 610. As an example, referring to FIG. 8, the edge ESD clamp circuit 640 may be provided by an active region 516 or the like formed below a power edge pad 543.

In some example embodiments illustrated in FIG. 13, a driver circuit 670 for outputting a data signal may be connected to the third center pad 663, and the pull-up device PU and pull-down device PD of the driver circuit 670 may be controlled by a control logic 680. The control logic 680 may be disposed in a peripheral circuit area provided below the third center pad 663.

Referring to FIG. 13, ESD protection elements 650 including a first ESD protection element 651 and a second ESD protection element 652 may be connected to the third center pad 663. For example, the first ESD protection device 651 is a PMOS device and may be connected between the first center pad 661 and the third center pad 663. The second ESD protection device 652 is an NMOS device and may be connected between the second center pad 662 and the third center pad 663. The first ESD protection device 651 and the second ESD protection device 652 may respectively be a MOS diode in which a drain and a gate are connected. Illustratively, referring to FIG. 9 together, the semiconductor element 510 having an active region 511 connected to a center pad 523 may provide a first ESD protection device 651 or a second ESD protection device 652.

In some example embodiments, as illustrated in FIG. 11, the ESD protection elements 650 may be connected to the center ESD clamp circuit 645. The center ESD clamp circuit 645 may include a capacitor element (C), a resistor element (R), a clamp switch element (CSW), and the like. A gate of the clamp switch element CSW may be connected to a node between the capacitor element C and the resistor element R. The center ESD clamp circuit 645 may be modified in various forms, and for example, may be replaced with the circuit illustrated in FIG. 12 or implemented as an SCR circuit.

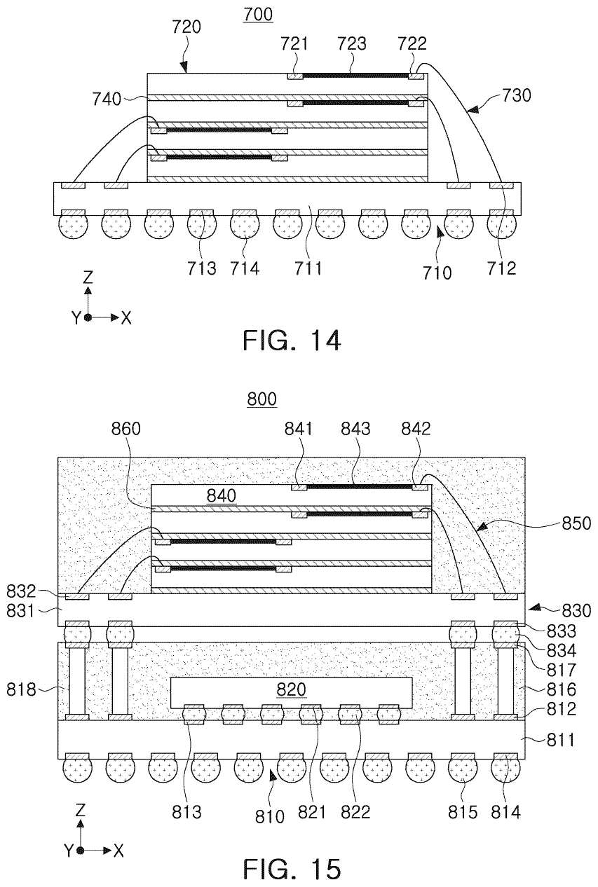

FIGS. 14 and 15 are schematic diagrams illustrating semiconductor packages according to example embodiments.

Referring first to FIG. 14, a semiconductor package 700 according to some example embodiments may include a package substrate 710, a plurality of semiconductor devices 720, a plurality of wires 730, and the like. The package substrate 710 may include a base substrate 711, upper pads 712, lower pads 713, and bumps 714.

One end of each of the plurality of wires 730 is connected to one of the upper pads 712, and the other end thereof may be connected to an edge pad 722 of one of the plurality of semiconductor devices 720. The plurality of semiconductor devices 720 may be stacked on each other by an adhesive layer 740.

Each of the plurality of semiconductor devices 720 may include center pads 721, edge pads 722, and redistribution patterns 723. The redistribution patterns 723 may extend in a first direction (X-axis direction) to connect the center pads 721 to the edge pads 722. The edge pads 722 may be disposed to be relatively higher than the center pads 721 in a vertical direction (Z-axis direction) perpendicular to the upper surface of the package substrate 710. For example, the edge pads 722 may be provided by exposing partial regions of the redistribution patterns 723 externally.

In some example embodiments illustrated in FIG. 14, portions of the plurality of semiconductor devices 720 may be stacked in a symmetrical structure. For example, first and second semiconductor devices disposed in a lower portion in the vertical direction are stacked such that the edge pads 722 are located on the left side in the first direction, and third and fourth semiconductor devices may be stacked such that the edge pads 722 are located on the right side in the first direction.

As in the previously described embodiments, at least portions of the redistribution patterns 723 in the plurality of respective semiconductor devices 720 may extend to both sides of the center pads 721. The redistribution patterns 723 extending to both sides of the center pads 721 may be connected to the edge pads 722 receiving power supply voltage, and be electrically connected to the ESD clamp circuits disposed below the edge pads 722.

Next, referring to FIG. 15, a semiconductor package 800 according to some example embodiments may have a package on package (POP) structure in which two packages are stacked on each other. For example, a lower package may include a processor 820 including a memory controller, and an upper package may include a plurality of memory devices 840.

Referring to FIG. 15, the lower package may include a lower package substrate 810, a processor 820, and the like. The lower package substrate 810 may include a base substrate 811, upper pads 812 and 813, lower pads 814, bumps 815, and the like. The pads 821 of the processor 820 may be connected to chip pads 813 among the upper pads 812 and 813 by chip bumps 822, and may be mounted on the lower package substrate 810 using a flip chip bonding method. Among the upper pads 812 and 813, the remaining upper pads 812 may be connected to upper pads 817 exposed on the upper surface of the insulating layer 818 through the vertical structure 816 inside the insulating layer 818.

The upper package may have a structure similar to the structure of the semiconductor package 700 previously described with reference to FIG. 14. The upper package includes an upper package substrate 830, a plurality of semiconductor devices 840, a plurality of wires 850, and the like, and the upper package substrate 830 may include a base substrate 831, upper pads 832, lower pads 833, and the like. The lower pads 833 of the upper package substrate 830 may be connected to the upper pads 817 exposed on the upper surface of the insulating layer 818 of the lower package by the package bumps 834.

The plurality of semiconductor devices 840 are stacked with each other by a plurality of insulating layers 860, and may be electrically connected to the upper pads 832 by the plurality of wires 850. For example, one ends of the plurality of wires 850 may be connected to the edge pads 842 of each of the plurality of semiconductor devices 840. The edge pads 842 are connected to the center pads 841 through redistribution patterns 843, and at least portions of the redistribution patterns 843 may extend to both sides of the center pads 841. The structure of the redistribution patterns 843 may be understood with reference to the above-described embodiments.

As set forth above, according to some example embodiments, the redistribution patterns connected to the edge pads receiving power supply voltage may be connected to a portion of uppermost wiring patterns disposed at the same height as the center pads in the semiconductor device through a plurality of uppermost vias. The plurality of uppermost vias are distributed on both sides of the center pads, and power integrity of the power supply voltage may be improved by lowering inductance and resistance of a path through which the power supply voltage is transmitted. In addition, semiconductor devices may be protected (or, for example, effectively protected) from ESD generated around the edge pads by implementing an ESD clamp circuit by disposing semiconductor devices below edge pads receiving power supply voltage and by the connection thereof to the edge pads.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While example embodiments have been illustrated and described above, it will be apparent to those skilled in the art that modifications and variations could be made without departing from the scope of the present inventive concepts as defined by the appended claims.

1. A semiconductor device comprising:
a semiconductor substrate;
a peripheral circuit area including an input/output circuit, a center electrostatic discharge (ESD) clamp circuit, and control logic;
a plurality of center pads above the peripheral circuit area in a vertical direction, orthogonal to an upper surface of the semiconductor substrate, and electrically connected to the input/output circuit and the center ESD clamp circuit;
a plurality of edge pads adjacent to a first edge of the semiconductor substrate and higher than the plurality of center pads in the vertical direction; and
a plurality of redistribution patterns extending in a first direction, parallel to the upper surface of the semiconductor substrate, and connected to the plurality of edge pads in the first direction,
at least one redistribution pattern, among the plurality of redistribution patterns, being connected to at least one uppermost wiring pattern at the same height as the plurality of center pads by a plurality of uppermost vias, on both sides of the plurality of center pads in the first direction.

2. The semiconductor device of claim 1, wherein in the first direction, a length of the at least one redistribution pattern is greater than a length of each of remaining redistribution patterns different from the at least one redistribution pattern.

3. The semiconductor device of claim 2, wherein the at least one redistribution pattern extends to an area adjacent to a second edge, parallel to the first edge.

4. The semiconductor device of claim 1, wherein the plurality of edge pads include a first edge power pad configured to receive a first power supply voltage, a second edge power pad configured to receive a second power supply voltage lower than the first power supply voltage, a third edge power pad configured to receive a third power supply voltage lower than the first power supply voltage and higher than the second power supply voltage, and edge signal pads configured to input and output a signal, respectively.

5. The semiconductor device of claim 4, wherein
the at least one redistribution pattern includes a first redistribution pattern connected to the first edge power pad and a second redistribution pattern connected to the second edge power pad, and
remaining redistribution patterns different from the at least one redistribution pattern include a third redistribution pattern connected to the third edge power pad and a center power pad among the plurality of center pads, and fourth redistribution patterns connected to the edge signal pads and center signal pads among the plurality of center pads.

6. The semiconductor device of claim 5, further comprising a plurality of wiring patterns between the plurality of redistribution patterns and the upper surface of the semiconductor substrate in the vertical direction, and including the at least one uppermost wiring pattern,
wherein
the at least one uppermost wiring pattern includes a first uppermost wiring pattern extending parallel to the first redistribution pattern, and a second uppermost wiring pattern extending parallel to the second redistribution pattern,
the first uppermost wiring pattern is connected to the first redistribution pattern by a plurality of first uppermost vias disposed on both sides of the plurality of center pads, and
the second uppermost wiring pattern is connected to the second redistribution pattern by a plurality of second uppermost vias on both sides of the plurality of center pads.

7. The semiconductor device of claim 6, wherein
the at least one uppermost wiring pattern is included in a plurality of uppermost wiring patterns at the same height as the plurality of center pads, and
at least portions of the uppermost wiring patterns are exposed and provide the plurality of center pads.

8. The semiconductor device of claim 1, further comprising a plurality of edge ESD clamp circuits adjacent to the first edge and connected to a first edge pad, among the plurality of edge pads, configured to receive a first power supply voltage and a second edge pad, among the plurality of edge pads, configured to receive a second power supply voltage.

9. The semiconductor device of claim 8, wherein the number of the plurality of edge ESD clamp circuits is equal to the number of the plurality of center ESD clamp circuits.

10. The semiconductor device of claim 7, wherein each of the plurality of edge ESD clamp circuits includes a resistor element connected to the first edge pad, a capacitor element connected to the second edge pad, a clamp element connected between the first edge pad and the second edge pad, and an inverter connected to the clamp element and a node between the resistor element and the capacitor element.

11. The semiconductor device of claim 1, wherein in the vertical direction, one of the plurality of center pads is between the at least one redistribution pattern and the semiconductor substrate.

12. The semiconductor device of claim 1, further comprising a plurality of bank regions on both sides of the peripheral circuit area in the first direction.

13. A semiconductor device comprising:
a device region having a semiconductor substrate, a plurality of bank regions including a plurality of memory cells on the semiconductor substrate, and a peripheral circuit area including a plurality of semiconductor elements on the semiconductor substrate;
a wiring region including a plurality of wiring patterns connected to the plurality of semiconductor elements and a plurality of center pads connected to the plurality of wiring patterns, and on the device region; and
a redistribution region including a plurality of redistribution patterns connected to at least a portion of the plurality of wiring patterns, and a plurality of edge pads connected to the plurality of redistribution patterns and adjacent to a first edge of the semiconductor substrate, and above the wiring region,
the device region including a first clamp circuit area adjacent to the first edge and below the plurality of edge pads, and a second clamp circuit area below the plurality of center pads.

14. The semiconductor device of claim 13, wherein a portion of the plurality of bank regions is between the first clamp circuit area and the second clamp circuit area in a first direction, parallel to an upper surface of the semiconductor substrate.

15. The semiconductor device of claim 13, wherein in the first direction, a distance between the first edge and the plurality of edge pads is smaller than a distance between the first edge and the plurality of center pads.

16. The semiconductor device of claim 13, wherein portions of the plurality of redistribution patterns extend to both sides of the plurality of center pads in the first direction.

17. The semiconductor device of claim 16, wherein remaining redistribution patterns among the plurality of redistribution patterns extend only to one side of the plurality of center pads in the first direction.

18. The semiconductor device of claim 17, wherein
the portions of the plurality of redistribution patterns are connected to the wiring region through a plurality of uppermost vias extending in a direction, perpendicular to an upper surface of the semiconductor substrate, and
the remaining redistribution patterns are connected to the wiring region through a portion of the plurality of center pads.

19. A semiconductor package comprising:
a package substrate including a plurality of pads exposed on an upper surface;
a semiconductor device on the package substrate, and including a semiconductor substrate, a plurality of edge pads adjacent to a first edge of the semiconductor substrate and exposed externally, and a plurality of redistribution patterns connected to the plurality of edge pads; and
a plurality of wires crossing the first edge and connecting the plurality of pads and the plurality of edge pads,
the semiconductor device connected to a first edge power pad configured to receive a first power supply voltage and a second edge power pad configured to receive a second power supply voltage lower than the first power supply voltage among the plurality of edge pads, and including edge clamp circuits adjacent to the first edge.

20. The semiconductor package of claim 19, wherein the semiconductor device includes a plurality of center pads, and a first redistribution pattern connected to the first edge power pad and a second redistribution pattern connected to the second edge power pad are separated from the plurality of center pads.

21.-22. (canceled)
